(19) United States
(12) Patent Application Publication
(10) Pub. No.: US 2026/0024585 A1
(43) Pub. Date: Jan. 22, 2026

(54) MEMORY DEVICE AND OPERATION THEREOF

(71) Applicant: YANGTZE MEMORY TECHNOLOGIES CO., LTD., Wuhan (CN)

(72) Inventors: Ke Ke, Wuhan (CN); Zhipeng Dong, Wuhan (CN); Jinchi Han, Wuhan (CN); Wei Huang, Wuhan (CN)

(21) Appl. No.: 18/783,132

(22) Filed: Jul. 24, 2024

(30) Foreign Application Priority Data
Jul. 19, 2024 (CN) 202410976313.4

(51) Int. Cl. G11C 16/10; G11C 16/04; G11C 16/12

(52) U.S. Cl. CPC G11C 16/102; G11C 16/0483; G11C 16/12

(57) ABSTRACT

In certain aspects, a memory device includes an array of memory cells, word lines respectively coupled to rows of the memory cells, and a peripheral circuit coupled to the array of memory cells through the word lines. Each memory cell is set to one of 2^{N} final levels corresponding to a piece of N-bits data, where N is an integer greater than 2. The peripheral circuit is configured to program, in a first pass, a select row of the rows of the memory cells, such that the memory cells in the selected row are set to k intermediate levels, where k is an integer not greater than 2^{N}. The peripheral circuit is also configured to, after the first pass, apply a single voltage pulse to a select word line of the word lines coupled to the select row of the memory cells, wherein an amplitude of the single voltage pulse changes over time. The peripheral circuit is further configured to, after applying the single voltage pulse, program, in a second pass, the select row of the memory cells, such that the memory cells in the selected row are set to the 2^{N} final levels.

### CROSS-REFERENCE TO RELATED APPLICATIONS

This application claims the benefit of priority to Chinese Application No. 202410976313.4, filed on Jul. 19, 2024, which is incorporated herein by reference in its entirety.

### BACKGROUND

The present disclosure relates to memory devices and operation methods thereof.

Flash memory is a low-cost, high-density, non-volatile solid-state storage medium that can be electrically erased and re-programmed. Flash memory includes NOR Flash memory and NAND Flash memory. Various operations can be performed by Flash memory, such as read, program (write), and erase. For NAND Flash memory, an erase operation can be performed at the block level, and a program operation or a read operation can be performed at the page level.

### SUMMARY

In one aspect, a memory device includes an array of memory cells, word lines respectively coupled to rows of the memory cells, and a peripheral circuit coupled to the array of memory cells through the word lines. Each memory cell is set to one of 2^{N} final levels corresponding to a piece of N-bits data, where N is an integer greater than 2. The peripheral circuit is configured to program, in a first pass, a select row of the rows of the memory cells, such that the memory cells in the selected row are set to k intermediate levels, where k is an integer not greater than 2^{N}. The peripheral circuit is also configured to, after the first pass, apply a single voltage pulse to a select word line of the word lines coupled to the select row of the memory cells, wherein an amplitude of the single voltage pulse changes over time. The peripheral circuit is further configured to, after applying the single voltage pulse, program, in a second pass, the select row of the memory cells, such that the memory cells in the selected row are set to the 2^{N} final levels.

In some implementations, the amplitude of the single voltage pulse decreases over time.

In some implementations, at least some of the memory cells in the select row are set to m pre-programmed levels by applying the single voltage pulse, where m is an integer not greater than 2^{N}−k.

In some implementations, the m pre-programmed levels are determined based on a Gray code for programming the select row of the memory cells.

In some implementations, N equals 4, k equals 4, and the m pre-programmed levels include P6, P7, P8, P9, P10, P11, and P14.

In some implementations, N equals 4, k equals 9, and the m pre-programmed levels include P3, P4, P6, P7, P9, P11, and P13.

In some implementations, the amplitude of the single voltage pulse includes m discrete values each lasting for a respective period.

In some implementations, a first memory cell of the at least some of the memory cells set to a highest level of the m pre-programmed levels is programmed in each of the m periods when applying the single voltage pulse.

In some implementations, a second memory cell of the at least some of the memory cells set to a lowest level of the m pre-programmed levels is programmed in a last one of the m periods when applying the single voltage pulse.

In some implementations, the second memory cell is inhibited in rest of the m periods when applying the single voltage pulse.

In some implementations, the peripheral circuit is configured to program the select row of the memory cells, such that the memory cells in the selected row are set to the 2^{N} final levels, immediately after applying the single voltage pulse without applying a verify voltage to the select word line there between.

In another aspect, a method for operating a memory device is provided. The memory device includes rows of memory cells. Each memory cell is set to one of 2^{N} final levels corresponding to a piece of N-bits data, where N is an integer greater than 2. In a first pass, a select row of the rows of the memory cells are programmed, such that the memory cells in the selected row are set to k intermediate levels, where k is an integer not greater than 2^{N}. After the first pass, a single voltage pulse is applied to a select word line coupled to the select row of the memory cells, wherein an amplitude of the single voltage pulse changes over time. After applying the single voltage pulse, in a second pass, the select row of the memory cells are programmed, such that the memory cells in the selected row are set to the 2^{N} final levels.

In some implementations, the amplitude of the single voltage pulse decreases over time.

In some implementations, at least some of the memory cells in the select row are set to m pre-programmed levels by applying the single voltage pulse, where m is an integer not greater than 2-k.

In some implementations, the m pre-programmed levels are determined based on a Gray code for programming the select row of the memory cells.

In some implementations, N equals 4, k equals 4, and the m pre-programmed levels include P6, P7, P8, P9, P10, P11, and P14.

In some implementations, N equals 4, k equals 9, and the m pre-programmed levels include P3, P4, P6, P7, P9, P11, and P13.

In some implementations, the amplitude of the single voltage pulse includes m discrete values each lasting for a respective period.

In some implementations, a first memory cell of the at least some of the memory cells set to a highest level of the m pre-programmed levels is programmed in each of the m periods when applying the single voltage pulse.

In some implementations, a second memory cell of the at least some of the memory cells set to a lowest level of the m pre-programmed levels is programmed in a last one of the m periods when applying the single voltage pulse.

In some implementations, the second memory cell is inhibited in rest of the m periods when applying the single voltage pulse.

In some implementations, programming the select row of the memory cells, such that the memory cells in the selected row are set to the 2^{N} final levels, occurs immediately after applying the single voltage pulse without applying a verify voltage to the select word line therebetween.

In still another aspect, a system includes a memory device configured to store data and a memory controller coupled to the memory device and configured to control the memory device. The memory device includes an array of memory cells, word lines respectively coupled to rows of the memory cells, and a peripheral circuit coupled to the array of memory cells through the word lines. Each memory cell is set to one of 2^{N} final levels corresponding to a piece of N-bits data, where N is an integer greater than 2. The peripheral circuit is configured to program, in a first pass, a select row of the rows of the memory cells, such that the memory cells in the selected row are set to k intermediate levels, where k is an integer not greater than 2^{N}. The peripheral circuit is also configured to, after the first pass, apply a single voltage pulse to a select word line of the word lines coupled to the select row of the memory cells, wherein an amplitude of the single voltage pulse changes over time. The peripheral circuit is further configured to, after applying the single voltage pulse, program, in a second pass, the select row of the memory cells, such that the memory cells in the selected row are set to the 2^{N} final levels.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a memory device including peripheral circuits, according to some aspects of the present disclosure.

FIG. 2 illustrates a side view of a cross-section of a memory cell array including a NAND memory string, according to some aspects of the present disclosure.

FIG. 3 illustrates a block diagram of a memory device including a memory cell array and peripheral circuits, according to some aspects of the present disclosure.

FIG. 4A illustrates an example of threshold voltage distributions of memory cells in a program operation, according to some aspects of the present disclosure.

FIG. 4B illustrates an example of threshold voltage distributions of memory cells in a read operation, according to some aspects of the present disclosure.

FIG. 5 illustrates a block diagram of a page buffer in a program operation, according to some aspects of the present disclosure.

FIGS. 6 and 7 illustrate waveforms of word line voltages applied to a select word line in a multi-pass program operation, according to some aspects of the present disclosure.

FIG. 8 illustrates timing diagrams of a program operation, according to some aspects of the present disclosure.

FIG. 9 illustrates waveforms of word line voltages applied to a select word line in a multi-pass program operation.

FIG. 10 illustrates an example of waveforms of word line voltages applied to a select word line in a multi-pass program operation, according to some aspects of the present disclosure.

FIG. 11A illustrates an example of a Gray code for the scheme of multi-pass program operation in FIG. 9, according to some aspects of the present disclosure.

FIG. 11B illustrates an example of threshold voltage distributions of memory cells applying the scheme of multi-pass program operation in FIG. 9, according to some aspects of the present disclosure.

FIG. 12 illustrates an example of a single voltage pulse used in the scheme of multi-pass program operation in FIG. 9, according to some aspects of the present disclosure.

FIG. 13A illustrates another example of a Gray code for the scheme of multi-pass program operation in FIG. 9, according to some aspects of the present disclosure.

FIG. 13B illustrates another example of threshold voltage distributions of memory cells applying the scheme of multi-pass program operation in FIG. 9, according to some aspects of the present disclosure.

FIG. 14 illustrates another example of a single voltage pulse used in the scheme of multi-pass program operation in FIG. 9, according to some aspects of the present disclosure.

FIG. 15 illustrates a flowchart of a method for operating a memory device, according to some aspects of the present disclosure.

FIG. 16 illustrates a block diagram of a system having a memory device, according to some aspects of the present disclosure.

FIG. 17A illustrates a diagram of a memory card having a memory device, according to some aspects of the present disclosure.

FIG. 17B illustrates a diagram of a solid-state drive (SSD) having a memory device, according to some aspects of the present disclosure.

The present disclosure will be described with reference to the accompanying drawings.

### DETAILED DESCRIPTION

In general, terminology may be understood at least in part from usage in context.

For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Memory devices, such as NAND Flash memory devices, can store more than a single bit of information into each memory cell in multiple levels (a.k.a., states) in order to increase the storage capacity and reduce the cost per bit. In program operations, the data may be programmed (written) into xLCs, such as multi-level cells (MLCs), trip-level cells (TLCs), quad-level cells (QLCs), etc. For xLCs, for example, QLCs, multi-pass program operations can be used to reduce program time (tPROG) and increase read window margin (RWM), which involve a coarse program pass that programs the xLCs to one of the intermediate levels, as well as a fine program pass that programs the xLCs from the intermediate levels to the final levels. For example, for QLCs, there are different schemes of two-pass program operations: a 16-16 scheme in which the memory cells are first programmed to 16 levels in the coarse programming to maximize the read window margin, and then re-programmed to form 16 levels with smaller threshold voltage ranges in the fine programming; and a K−16 scheme in which the memory cells are first programmed to K levels in the coarse programming (K<16, e.g., 4, 8, or 9), and then programmed to 16 levels in the fine programming.

For some K−16 schemes, however, the read window margin may not be as sufficient as a 16-16 scheme, i.e., the threshold (Vth) voltage distribution is not tighter enough. To enlarge the read window margin, multiple voltage pulses may be applied to the select word line after coarse programming to pre-program at least some of the select memory cells to pre-programmed levels before fine programming. The multiple voltage pulses used for pre-programming, however, can increase the program time (tPROG) due to multiple rises-and-falls of voltages on the select word line, which can affect the performance of memory devices.

To address one or more of the aforementioned issues, the present disclosure introduces a pre-programming scheme of multi-pass program operation that uses a single voltage pulse with amplitude changes over time, instead of multiple voltage pluses. The program time can be reduced, and the performance of the memory devices can be improved. In some implementations, the amplitude of the single voltage pulse decreases over time, for example, having discrete values, each lasting for a respective period, and in each period (except the first period), the single voltage pulse is applied to memory cells set to multiple pre-programmed levels. That is, memory cells (except those set to the lowest pre-programmed level) can be repeatedly programmed in more than one time period when applying the single voltage pulses, thereby further tightening the threshold voltage distribution and enlarging the read window margin of the memory cells due to Vth-3σ improvement.

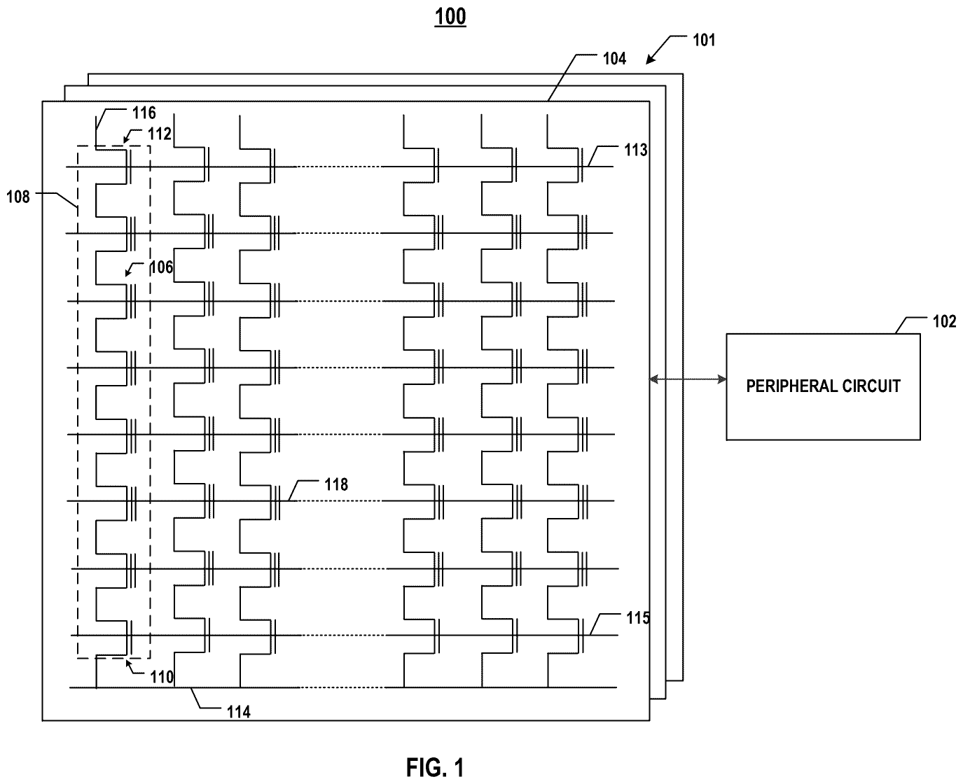

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge, which depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is an SLC that has two possible levels (memory states) and thus, can store one bit of data. For example, the first state “0” can correspond to a first range of threshold voltages, and the second state “1” can correspond to a second range of threshold voltages. In some implementations, each memory cell 106 is an xLC that is capable of storing more than a single bit of data in more than four levels. For example, the xLC may store two bits per cell (MLC), three bits per cell (TLC), or four bits per cell (QLC)). Each xLC can be programmed to assume a range of possible nominal storage values (i.e., corresponding to 2^{N} pieces of N-bits data). In some implementations, each memory cell 106 is set to one of 2^{N} final levels corresponding to a piece of N-bits data, where N is an integer greater than 2.

As shown in FIG. 1, each NAND memory string 108 can also include a source select gate (SSG) transistor 110 at its source end and a drain select gate (DSG) transistor 112 at its drain end. SSG transistor 110 and DSG transistor 112 can be configured to activate select NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. The drain of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage to the gate of respective DSG transistor 112 through one or more DSG lines 113 and/or by applying a select voltage or a deselect voltage to the gate of respective SSG transistor 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a select block 104, source lines 114 coupled to select block 104 as well as unselect blocks 104 in the same plane as select block 104 can be biased with an erase voltage (Vers), such as a high positive bias voltage (e.g., 20 V or more). Memory cells 106 of adjacent NAND memory strings 108 can be coupled through word lines 118 that select which row of memory cells 106 is affected by read and program operations. In some implementations, each word line 118 is coupled to a plurality of memory cells 106. Each word line 118 can include a plurality of control gates (gate electrodes) at each memory cell 106 and a gate line coupling the control gates.

As shown in FIG. 1, memory cell array 101 can include an array of memory cells 106 in a plurality of rows and a plurality of columns in each block 104. One column of memory cells corresponds to one NAND memory string 108, according to some implementations. The plurality of rows of memory cells 106 can be respectively coupled to word lines 118, and the plurality of columns of memory cells 106 can be respectively coupled to bit lines 116. Peripheral circuit 102 can be coupled to memory cell array 101 through bit lines 116 and word lines 118.

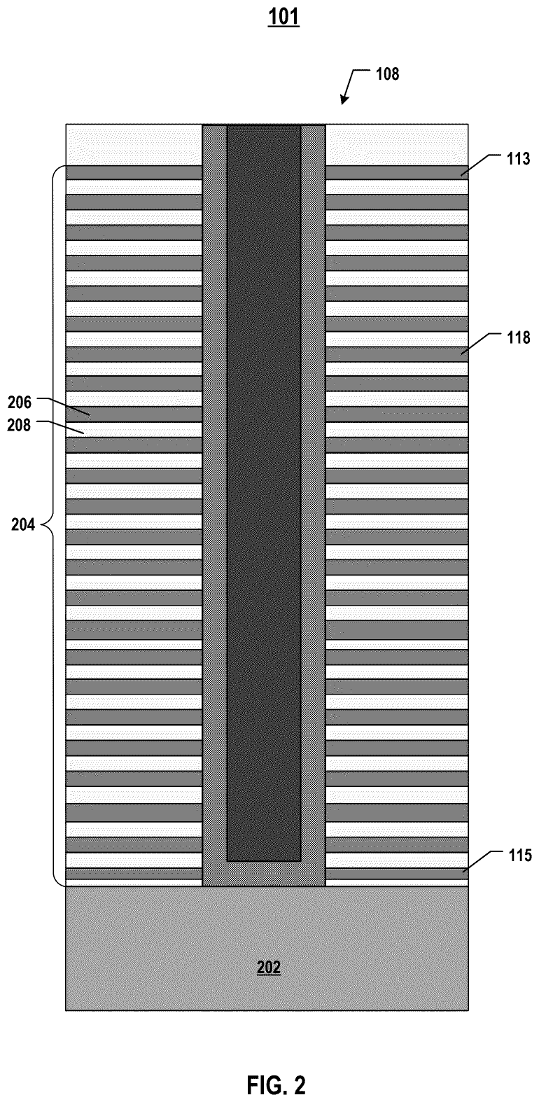

FIG. 2 illustrates a side view of a cross-section of memory cell array 101 including NAND memory string 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding memory cells 106, the gates of DSG transistors 112, or the gates of SSG transistors 110, and can extend laterally as DSG line 113 at the top of memory stack 204, SSG line 115 at the bottom of memory stack 204, or word line 118 between DSG line 113 and SSG line 115.

As shown in FIG. 2, NAND memory string 108 includes a channel structure extending vertically through memory stack 204. In some implementations, the channel structure includes a channel hole filled with semiconductor material(s) (e.g., as a semiconductor channel) and dielectric material(s) (e.g., as a memory film). It is understood that although not shown in FIG. 2, additional components of memory cell array 101 can be formed including, but not limited to, gate line slits/source contacts, local contacts, interconnect layers, etc.

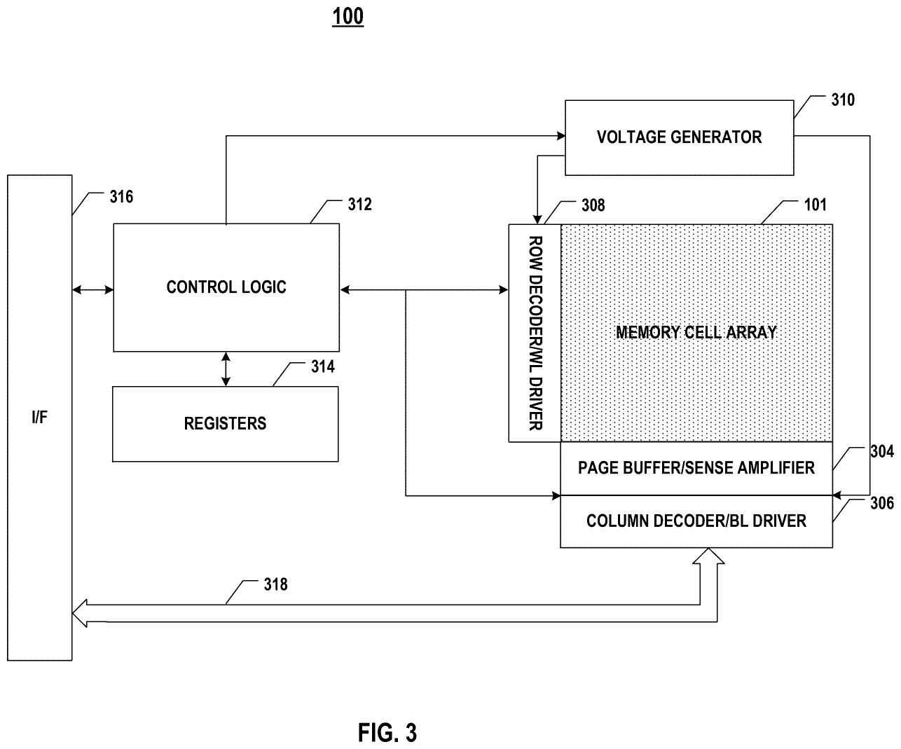

Referring back to FIG. 1, peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each select memory cell 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some exemplary peripheral circuits including a page buffer/sense amplifier 304, a column decoder/bit line driver 306, a row decoder/word line driver 308, a voltage generator 310, control logic 312, registers 314, an interface (I/F) 316, and a data bus 318. It is understood that in some examples, additional peripheral circuits not shown in FIG. 3 may be included as well.

Page buffer/sense amplifier 304 can be configured to sense (read) and program (write) data from and to memory cell array 101 according to the control signals from control logic 312. In one example, page buffer/sense amplifier 304 may store one or more pages of program data (write data, referred to herein as “data page”) to be programmed into memory cell array 101. In another example, page buffer/sense amplifier 304 may verify programmed select memory cells 106 in each program/verify cycle in a program operation to ensure that the data has been properly programmed into memory cells 106 coupled to select word lines 118. In still another example, page buffer/sense amplifier 304 may also sense the low power signals from bit line 116 that represents a data bit stored in memory cell 106 and amplify the small voltage swing to recognizable logic levels in a read operation.

Column decoder/bit line driver 306 can be configured to be controlled by control logic 312 and select one or more NAND memory strings 108 by applying bit line voltages generated from voltage generator 310. Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Voltage generator 310 can be configured to be controlled by control logic 312 and generate the word line voltages (e.g., read voltage, program voltage, channel pass voltage, supply voltage, verify voltage, etc.), bit line voltages, and source line voltages to be supplied to memory cell array 101.

Control logic 312 can be coupled to each peripheral circuit described above and configured to control the operations of each peripheral circuit. Registers 314 can be coupled to control logic 312 and include status registers, command registers, and address registers for storing status information, command operation codes (OP codes), and command addresses for controlling the operations of each peripheral circuit. Interface 316 can be coupled to control logic 312 and act as a control buffer to buffer and relay control commands received from a memory controller (not shown) and/or a host (not shown) to control logic 312 and status information received from control logic 312 to the memory controller and/or the host. Interface 316 can also be coupled to column decoder/bit line driver 306 via data bus 318 and act as a data input/output (I/O) interface and a data buffer to buffer and relay the data to and from memory cell array 101.

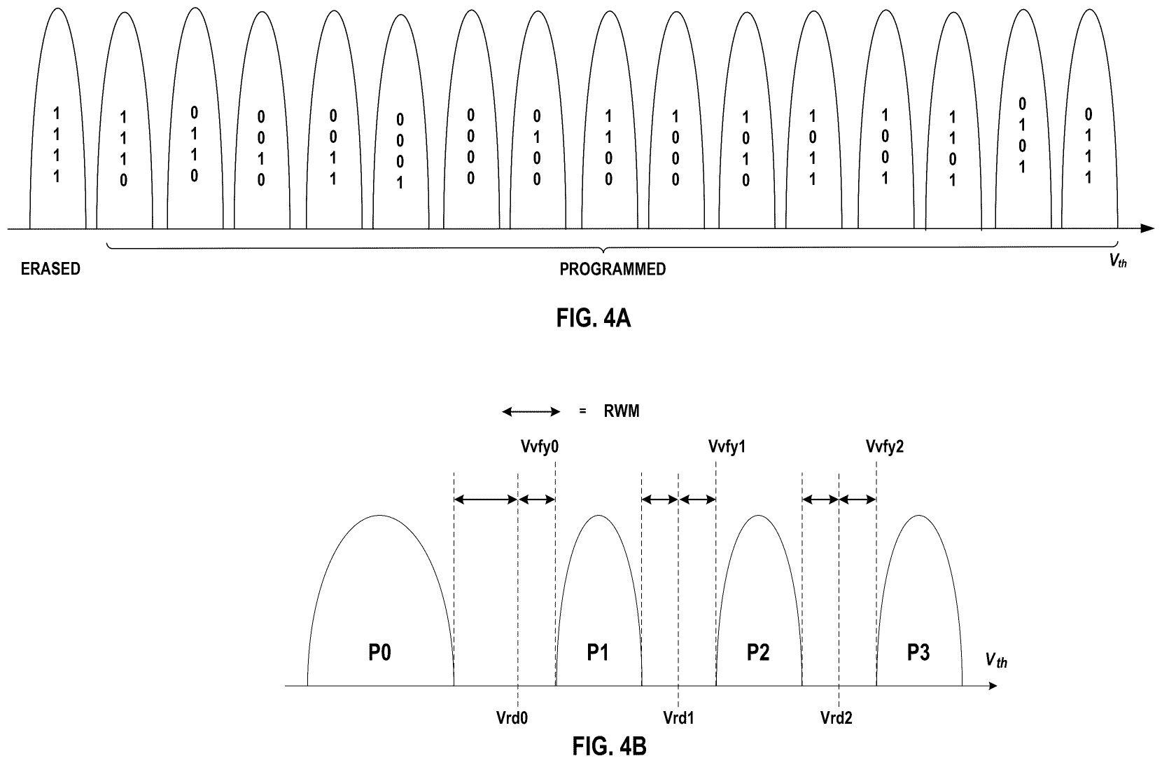

FIG. 4A illustrates an example of threshold voltage distributions of memory cells in a program operation, according to some aspects of the present disclosure. As described above, each memory cell 106 can be configured to be set to one of 2^{N} final levels corresponding to a piece of N-bits data, where N is an integer greater than 2 (e.g., N=3 for TLCs, N=4 for QLCs, etc.). Each level can correspond to one of 2^{N} threshold voltage (Vth) ranges of memory cells 106. Considering a multi-pass program operation in which memory cell 106 may be programmed into an intermediate level first in a coarse program pass (a.k.a., coarse programming), the “level” referred to herein may be considered as the final level after the fine program pass (a.k.a., fine programming) of the multi-pass program operation, in contrast to the intermediate level. Taking QLCs, where N=4, for example, as shown in FIG. 4A, memory cell 106 may be set into one of the 16 levels, including one level of the erased state and 15 levels of the programmed states. Each level may correspond to a respective threshold voltage range of memory cells 106. For example, the level corresponding to the lowest threshold voltage range (the left-most threshold voltage range in FIG. 4A) may be considered as level 0 (P0), the level corresponding to the second-lowest threshold voltage range (the second left-most threshold voltage range in FIG. 4A) may be considered as level 1 (P1), and so until level 15 (P15) corresponding to the highest threshold voltage range (the right-most threshold voltage range in FIG. 4A).

On the other hand, each level can correspond to one of the 2^{N} pieces of N-bits data. In some implementations, the 2^{N} pieces of N-bits data may be represented by (in the form of) a Gray code. A Gray code (a.k.a., reflected binary code (RBC) or reflected binary (RB)) is an ordering of the binary numeral system such that two successive values differ in only one bit (binary digit). For example, TABLE 1 below shows an example of a binary code representing a one-to-one mapping between 16 levels (P0 to P15) and 16 pieces of 4-bits data used in the example of FIG. 4A. As shown in TABLE 1, each piece of 4-bits data may consist of four bits of binary values (b1, b2, b3, and b4). In one example, level 1 may correspond to a piece of 4-bits data having a value of 1111. In another example, level 15 may correspond to another piece of 4-bits data having a value of 1110.

TABLE 1

| Lvl | P0 | P1 | P2 | P3 | P4 | P5 | P6 | P7 | P8 | P9 | P10 | P11 | P12 | P13 | P14 | P15 |
|---|---|---|---|---|---|---|---|---|---|---|---|---|---|---|---|---|
| b1 | 1 | 1 | 0 | 0 | 0 | 0 | 0 | 0 | 1 | 1 | 1 | 1 | 1 | 1 | 0 | 0 |
| b2 | 1 | 1 | 1 | 0 | 0 | 0 | 0 | 1 | 1 | 0 | 0 | 0 | 0 | 1 | 1 | 1 |
| b3 | 1 | 1 | 1 | 1 | 1 | 0 | 0 | 0 | 0 | 0 | 1 | 1 | 0 | 0 | 0 | 1 |
| b4 | 1 | 0 | 0 | 0 | 1 | 1 | 0 | 0 | 0 | 0 | 0 | 1 | 1 | 1 | 1 | 1 |

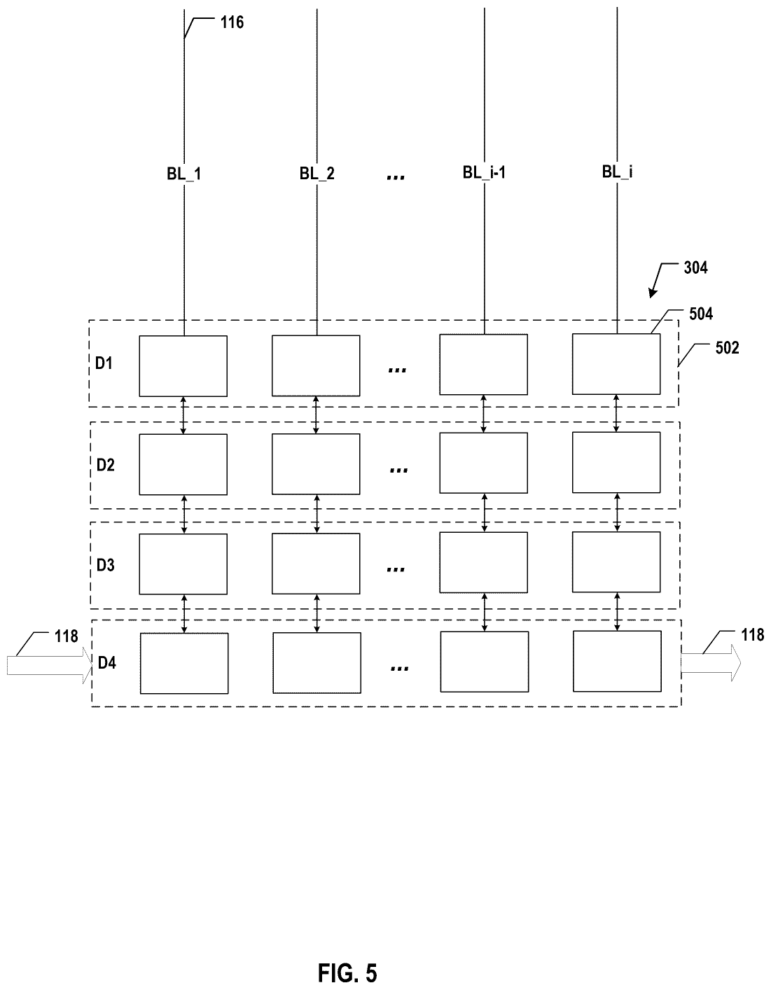

Also referring to FIG. 3, in a program operation, N data pages of the N-bits data transmitted through data bus 318 can be temporarily stored in page buffer/sense amplifier 304, and page buffer/sense amplifier 304 can be configured to provide to each target memory cell 106 the corresponding piece of N-bits data through the corresponding bit line 116. For example, FIG. 5 illustrates a block diagram of exemplary page buffer/sense amplifier 304 in a program operation, according to some aspects of the present disclosure. In some implementations, page buffer/sense amplifier 304 includes N storage modules 502 (e.g., latches and/or caches) each configured to temporarily store one of N data pages. That is, the N-bits data (having 2^{N} values) to be stored by a row of target memory cells 106 coupled to a selected word line 118 can be transmitted, stored, and provided in the form of N data pages of N-bits data in a program operation.

Still taking QLCs, where N=4, for example, as shown in FIG. 5, page buffer/sense amplifier 304 may include 4 storage modules 502 (D1, D2, D3, and D4) each configured to temporarily store one of 4 data pages. Each storage module 502 may include i storage units 504 (e.g., registers) corresponding to i target memory cells 106 in a row of memory cells 106 coupled to a selected word line 118 in a program operation. That is, each target memory cell 106 may be coupled to a corresponding set of four storage units 504 of each of four storage modules 502 (D1, D2, D3, and D4) through a respective bit line 116 (BL_1, BL_2, . . . , BL_i−1, or BL_i). For each target memory cell 106 in a program operation, the four bits of binary values in the corresponding piece of 4-bits data (e.g., b1, b2, b3, and b4 according to the gray code in TABLE 1) may be temporarily stored in the corresponding set of four storage units 504, respectively, such that the corresponding piece of 4-bits data may be provided to target memory cell 106 by page buffer/sense amplifier 304.

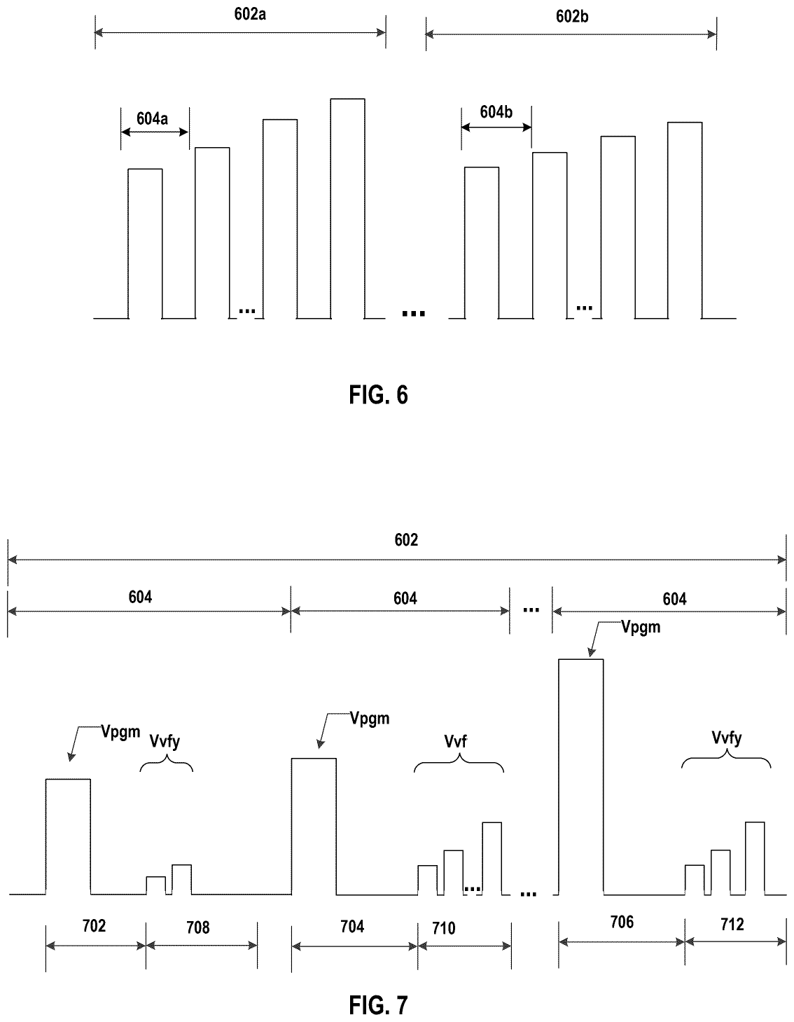

To perform a program operation, in addition to page buffer/sense amplifier 304 providing to each target memory cell 106 the corresponding piece of N-bits data, row decoder/word line driver 308 can be configured to apply program voltages and verify voltages to a selected word line 118 coupled to a row of target memory cells 106 in one or more program/verify cycles (loops) in order to raise the threshold voltage of each target memory cell 106 to a desired level (into a desired range of threshold voltages) based on the corresponding piece of N-bits data. For example, FIGS. 6 and 7 illustrate an example of waveforms of word line voltages applied to a select word line in a multi-pass program operation, according to some aspects of the present disclosure. As shown in FIG. 6, the multi-pass program operation includes at least a first pass 602a (e.g., a coarse program pass) and a second pass 602b (e.g., a fine program pass) after first pass 602a. First pass 602a includes one or more program/verify cycles 604a, and second pass 602b includes one or more program/verify cycles 604b as well.

As shown in FIG. 7, in each program/verify cycle 604 of a pass 602, regardless of whether it is in first pass 602a or second pass 602b, a program voltage (Vpgm) is applied to the selected word line, followed by a number of verify voltages (Vvfy) with incremental changes of voltage levels. As shown in FIG. 7, in each program/verify cycle 604, row decoder/word line driver 308 can be configured to apply a program voltage (Vpgm) on select word line 118 to select row of memory cells 106 in a program cycle 702, 704, . . . , or 706 and sequentially apply one or more verify voltages (Vvfy) with incremental changes of voltage levels to verify select row of memory cells 106 in a verify cycle 708, 710, . . . , or 712. That is, peripheral circuit 102 can perform verification of select row of memory cells 106 at one or more levels in verify cycle 708, 710, . . . , or 712 after applying a program voltage in program cycle 702, 704, . . . , or 706. The total number of verify voltages applied in all verify cycles 708, 710, . . . , and 712 in pass 602 depends on the level being programmed in pass 602, according to some implementations. As a result, at the end of the program operation, select memory cell 106 can be programmed into one of the 2^{N} levels based on the corresponding N bits of data to be stored in select memory cell 106.

Multi-pass program operations can be implemented using any suitable k−2^{N} schemes (where k is an integer not greater than 2^{N}) in which the number of intermediate levels k is the same as the number of final levels 2^{N} (e.g., 16-16 schemes for QLCs), or the number of intermediate levels k is smaller than the number of final levels 2^{N}(e.g., 4-16 schemes or 9-16 schemes for QLCs). In a multi-pass program operation, in the fine program pass (e.g., the last program pass that programs each target memory cell 106 into a final level), each target memory cell 106 can be set into one of the 2^{N} final levels. As to the coarse program pass (e.g., any non-last program pass that programs each target memory cell 106 into an intermediate level), each target memory cell 106 is set into one of the k intermediate levels (where k<2^{N}).

As shown in FIGS. 6 and 7, the number of different verify voltages applied in all verify cycles 708, 710, . . . , and 712 in first pass 602a can determine the number of intermediate levels into which target memory cell 106 can be set in the coarse program pass, and the number of different verify voltages applied in all verify cycles 708, 710, . . . , and 712 in second pass 602b can determine the number of final levels into which target memory cell 106 can be set in the fine program pass. In some implementations, in a coarse program pass, (k−1) verify voltages are applied in all verify cycles 708, 710, . . . , and 712 by word line driver 308 to select word line 118 to form k intermediate levels, while in a fine program pass, (2^{N}−1) verify voltages are applied in all verify cycles 708, 710, . . . , and 712 by word line driver 308 to select word line 118 to form 2^{N} final levels.

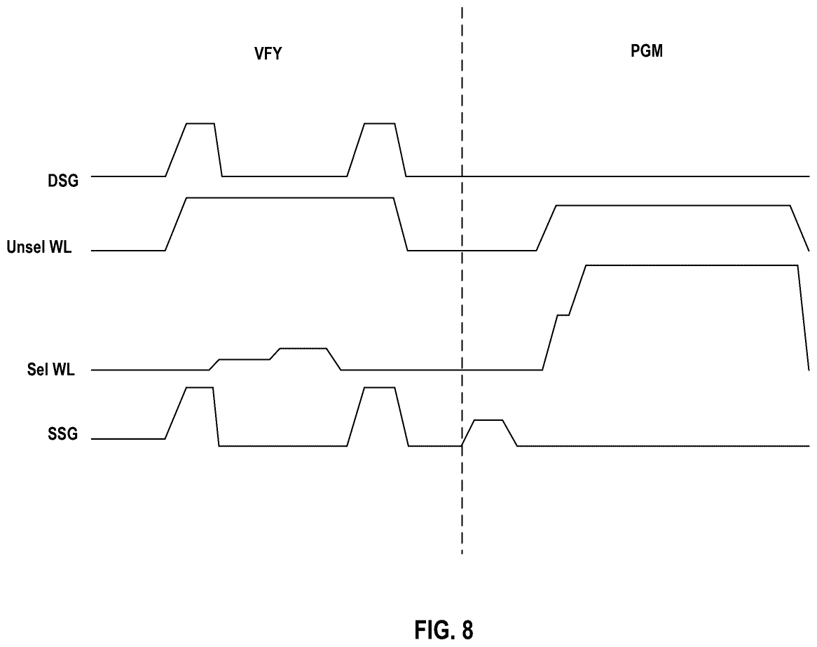

FIG. 8 illustrates timing diagrams of a program operation, according to some aspects of the present disclosure. FIG. 8 shows one verify cycle (VFY, e.g., 708, 710, . . . or 712) and one program cycle (PGM, e.g., 702, 704, . . . , or 706). In the verify cycle, a verify voltage can be applied to the select word line (sel WL) to verify select memory cell 106 coupled to select word line 118 at one or more levels. A pass voltage can be applied to each unselect word line 118 (unsel WL) to turn on unselect memory cells 106 coupled to unselect word lines 118. For an unselect NAND memory string 108, a deselect voltage (e.g., a ground voltage) can be applied to DSG line 113 (DSG) and SSG line 115 (SSG) to turn off DSG transistor 112 and SSG transistor 110 when applying the verify voltage to select word line 118 to inhibit the verification of unselect memory cells 106 in the verify cycle. As shown in FIG. 8, before applying the verify voltage to select word line 118, a select (positive) voltage can be applied to DSG line 113 and SSG line 115 to turn on DSG transistor 112 and SSG transistor 110 in order to decrease the channel potential and reduce hot carrier injection (HCl) before applying the verify voltage. Similarly, after applying the verify voltage, a select (positive) voltage can be applied to DSG line 113 and SSG line 115 to turn on DSG transistor 112 and SSG transistor 110 again in order to increase the channel potential and reduce HCl before the program cycle.

As shown in FIG. 8, in the program cycle, a program voltage can be applied to select word line 118 to program select memory cells 106, and a pass voltage can be applied to each unselect word line 118 to turn on unselect memory cells 106. Before applying the program and pass voltages, a select (positive) voltage can be applied to SSG line 115 to turn on SSG transistor 110, and a bias (positive) voltage (not shown) may be applied to source line 114 to pull electrons accumulated in the channel between select memory cell 106 and the source of unselect NAND memory string 108.

FIG. 4B illustrates an example of threshold voltage distributions of memory cells in a read operation, according to some aspects of the present disclosure. As shown in FIG. 4B, verify voltages Vvfy0, Vvfy1, and Vvfy2 can define the threshold voltage ranges of the corresponding levels P1, P2, and P3, respectively, by setting the lower bounds (3σ) of the threshold voltage ranges. The widths of the threshold voltage ranges can be set, for example, by the corresponding program voltage Vpgm (shown in FIG. 7). The read window margins (RWM) between adjacent levels (threshold voltage ranges), as well as the read voltages Vrd, thus can be defined by the verify voltages Vvfy and program voltage Vpgm. For example, by adjusting the verify voltages Vvfy0, Vvfy1, and Vvfy2 during program operations, the read window margins between levels P0, P1, P2, and P3, as well as the corresponding read voltages Vrd0, Vrd1, and Vrd2 between levels P0, P1, P2, and P3 may be adjusted, respectively.

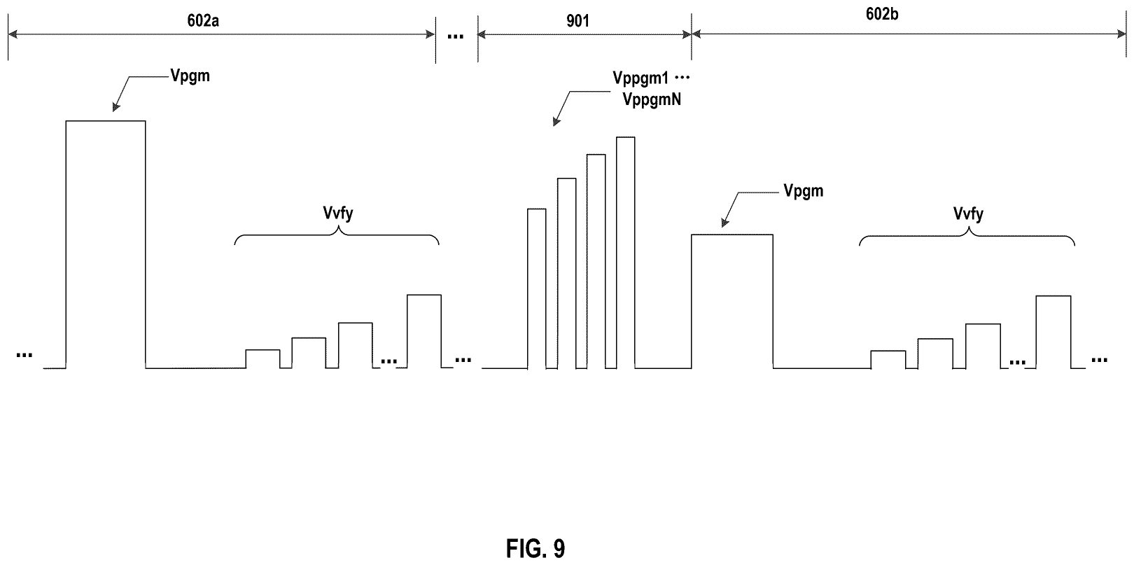

FIG. 9 illustrates waveforms of word line voltages applied to a select word line in a multi-pass program operation. To increase the read window margins, in this example, pre-programming 901 is performed between first pass 602a (e.g., after the last program/verify cycles 604a) and second pass 602b (e.g., before the first program/verify cycles 604b). In pre-programming 901, multiple voltage pulses Vppgm1, . . . , VppgmN are applied to the select word line to program some of the select memory cells from one or more immediate levels to one or more pre-programmed levels, which are then programmed from the pre-programmed levels to the final levels in second pass 602a. It is understood that pre-programming 901 may not be performed on the select word line immediately after first pass 602a is performed on the same select word line. As shown in FIG. 9, the amplitudes of multiple voltage pulses Vppgm1, . . . , VppgmN increase, following incremental step pulse programming (ISPP). However, since each time when a voltage pulse voltage is applied to the select word line, the voltage applied on each word line (e.g., the program voltage on the select word line and the pass voltage on the unselect word line) needs to first ramp up (rise) from the supply voltage (e.g., Vdd or ground) to the desired amplitude, and eventually ramp down (fall) from the desired amplitude to the supply voltage (e.g., Vdd or ground), which significantly increases the program time.

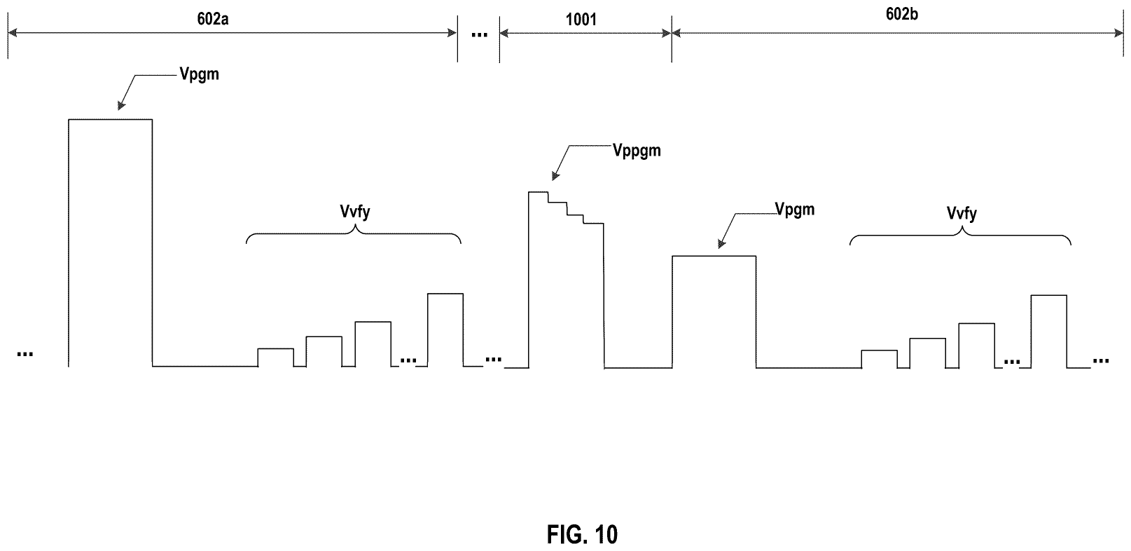

Consistent with the scope of the present disclosure, a pre-programming scheme of multi-pass program operation that uses a single voltage pulse with amplitude changes over time, instead of multiple voltage pluses, is applied, for example, as shown in FIG. 10. As shown in FIG. 10, pre-programming 1001 can be performed between first pass 602a (e.g., after the last program/verify cycles 604a) and second pass 602b (e.g., before the first program/verify cycles 604b) to enlarge the read window margins. In some implementations, programming 901 is not performed on select word line 118 immediately after first pass 602a is performed on same select word line 118. Instead, after first pass 602a is performed on select word line 118, first pass 602a is performed on an adjacent word line 118, and programming 901 is then performed on select word line 118 after first pass 602 is performed on adjacent word line 118, according to some implementations. In pre-programming 1001, a single voltage pulse Vppgm can be applied to select word line 118 to program at least some of select memory cells 106 from one or more immediate levels to one or more pre-programmed levels, which can then be programmed from the pre-programmed levels to the final levels in second pass 602a. In this pre-programming scheme of FIG. 10, since the voltage applied on each word line (e.g., the program voltage on the select word line and the pass voltage on the unselect word line) only needs to ramp up (rise) from the supply voltage (a.k.a. default voltage, e.g., Vdd or ground) to the desired amplitude, and ramp down (fall) from the desired amplitude to the supply voltage (e.g., Vdd or ground) once, the program time can be reduced compared with the example in FIG. 9.

In some implementations, the amplitude of the single voltage pulse Vppgm changes over time. For example, as shown in FIG. 10, the amplitude of the single voltage pulse Vppgm decreases over time. In some implementations, the amplitude of the single voltage pulse Vppgm includes a plurality of discrete values each lasting for a respective period. For example, as shown in FIG. 10, the amplitude of the single voltage pulse Vppgm includes four decreasing discrete values each lasting for a respective period. It is understood that although the amplitude of the single voltage pulse Vppgm falls between adjacent values, the word line voltage does not fall all the way to the supply voltage (e.g., Vdd or ground) and does not then rise back to the next value of the amplitude. Instead, the word line voltage falls from the current value to the next value of the amplitude directly. This is different from the example of FIG. 9 in which the word line voltage falls all the way to the supply voltage (e.g., Vdd or ground) and then rises back to the desired amplitude of the next voltage pulse between adjacent voltage pulses.

In some implementations, pre-programming 1001 is performed without verification to further reduce the program time. For example, as shown in FIG. 10, second pass 602 may be performed immediately after applying the single voltage pulse Vppgm without applying a verify voltage Vvfy to select word line 118. That is, pre-programming 1001 includes only a program cycle without any verify cycle, i.e., it does not include a complete program/verify cycle 604, according to some implementations.

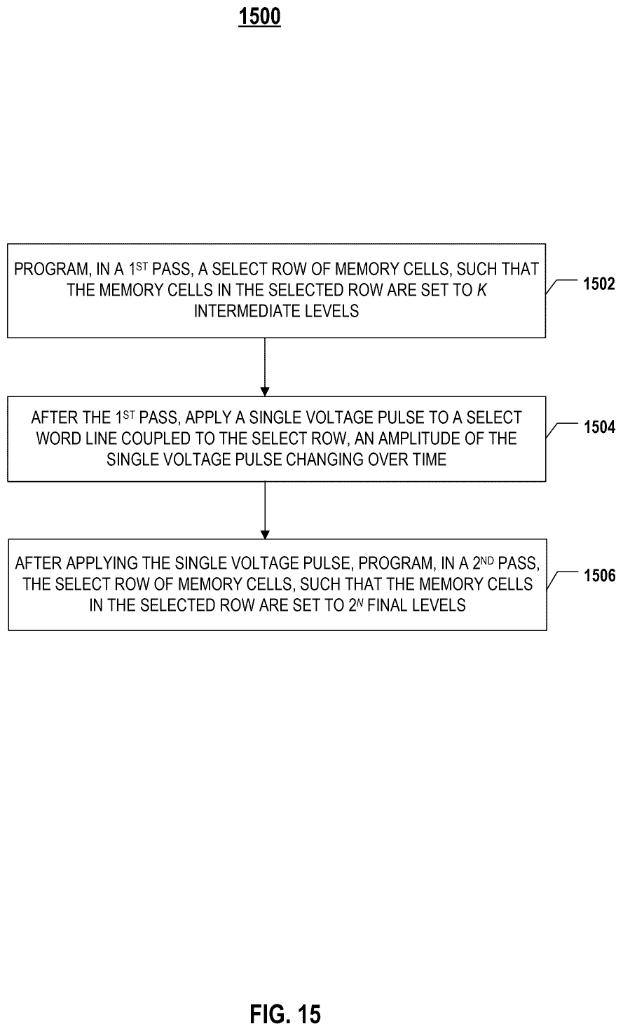

FIG. 15 illustrates a flowchart of a method 1500 for operating a memory device, according to some aspects of the present disclosure. The memory device may be any suitable memory device disclosed herein, such as memory device 100. Method 1500 may be implemented by peripheral circuit 102, such as row decoder/word line driver 308, page buffer/sense amplifier 304, and control logic 312. It is understood that the operations shown in method 1500 may not be exhaustive and that other operations can be performed as well before, after, or between any of the illustrated operations. Further, some of the operations may be performed simultaneously, or in a different order than shown in FIG. 15.

Referring to FIG. 15, method 1500 starts at operation 1502, in which a select row of memory cells are programmed, in a first pass, such that the memory cells in the selected row are set to k intermediate levels, where k is an integer not greater than 2^{N}. In some implementations, each memory cell is set to one of 2^{N} final levels corresponding to a piece of N-bits data, where N is an integer greater than 2. In some implementations, the select row of memory cells are programmed, in the first pass, based on N data pages. In some implementations, the k intermediate levels are determined based on a Gray code for programming the select row of the memory cells.

For example, in a multi-pass program operation, peripheral circuit 102 can be configured to program, in first pass 602a (e.g., a coarse program pass), a select row of memory cells 106 based on N data pages, such that each memory cell 106 of the selected row is set to one of k intermediate levels. Each memory cell 106 is set to one of 2^{N} final levels corresponding to a piece of N-bits data, where N is an integer greater than 2, and k is an integer not greater than 2^{N} The k intermediate levels can correspond to k threshold voltage ranges, respectively, of the select row of memory cells 106. In some implementations, to program the select row of memory cells 106 in first pass 602a, word line driver 308 is configured to apply, in program cycle 702, 704, . . . , or 706, a first program voltage Vpgm (e.g., a coarse program voltage) to a select word line 118 to which the select row of memory cells 106 are coupled, and then apply, in verify cycle 708, 710, . . . , or 712, a set of first verify voltages Vvfy (e.g., coarse verify voltages) to select word line 118 for verifying and thus, forming the intermediate levels. For example, the set of coarse verify voltages may include (k−1) verify voltages for verifying and forming k intermediate levels in first pass 602a.

Method 1500 proceeds to operation 1504, as illustrated in FIG. 15, in which, after the first pass, a single voltage pulse is applied to a select word line coupled to the select row of the memory cells. The amplitude of the single voltage pulse changes over time. In some implementations, programming the select row of the memory cells, such that the memory cells in the selected row are set to the 2^{N} final levels, occurs immediately after applying the single voltage pulse without applying a verify voltage to the select word line therebetween.

For example, in the multi-pass program operation, peripheral circuit 102 can be configured to, after first pass 602a (e.g., a coarse program pass), apply a single voltage pulse, having an amplitude changes over time, to select word line 118. For example, as shown in FIG. 10, the single voltage pulse Vppgm may be applied for pre-programming 1001 between first pass 602a and second pass 602b. The amplitude of the single voltage pulse Vppgm may change, e.g., decreases, over time. Second pass 602 may occur immediately after applying the single voltage pulse Vppgm without applying any verify voltage Vvfy to select word line 118 between applying the single voltage pulse Vppgm and second pass 602.

In some implementations, at least some of the memory cells in the select row are set to m pre-programmed levels by applying the single voltage pulse, where m is an integer not greater than 2^{N}−k. In some implementations, the m pre-programmed levels are determined based on a Gray code for programming the select row of the memory cells.

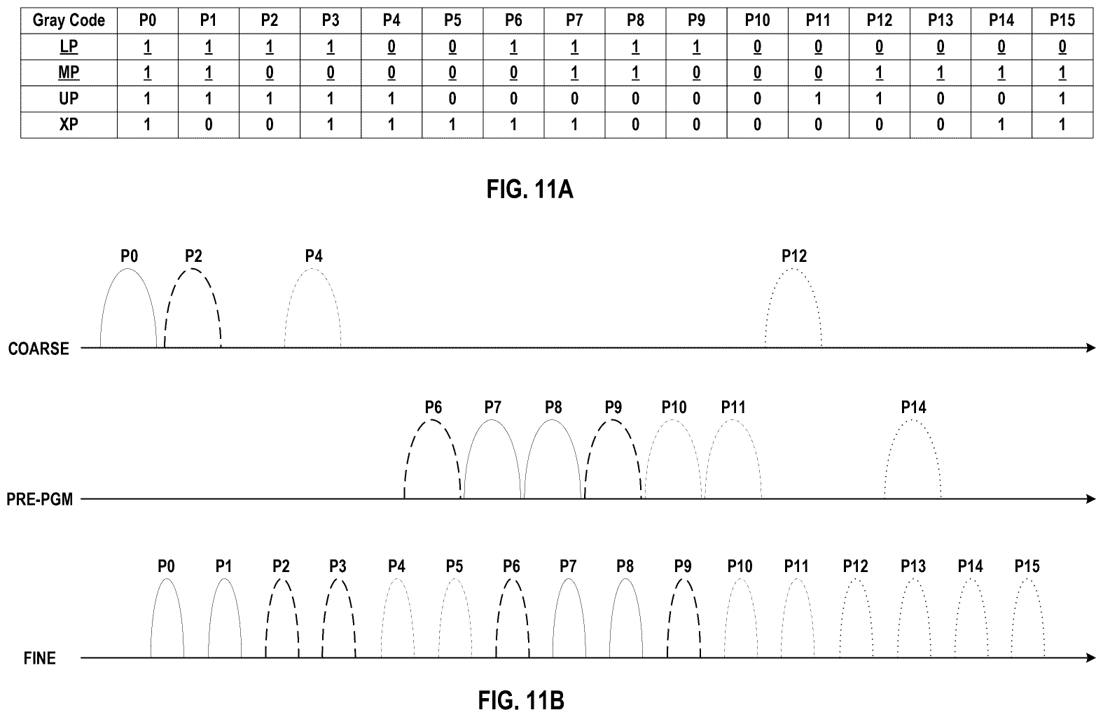

For example, FIG. 11A illustrates an example of a Gray code for the scheme of multi-pass program operation in FIG. 9, according to some aspects of the present disclosure. FIG. 11B illustrates an example of threshold voltage distributions of memory cells applying the scheme of multi-pass program operation in FIG. 9, according to some aspects of the present disclosure. In this scheme, N equals 4, k equals 4 (e.g., a 4-16 scheme for QLCs), and the m pre-programmed levels include P6, P7, P8, P9, P10, P11, and P14. As shown in FIG. 11A, four data pages (N=4 for QLCs) include a lower page LP, a middle page MP, an upper page UP, and an extra page XP, which are used for programming memory cells 106 into 4 intermediate levels by the coarse program pass and 16 final levels by the fine program pass according to the Gray code. As shown in FIGS. 11A and 11B, 4 intermediate levels include P0 (11 for LP and MP), P2 (10 for LP and MP), P4 (00 for LP and MP), and P12 (01 for LP and MP), according to some implementations. In some implementations, each intermediate level corresponds to one or more final levels that have the same values of lower page LP and middle page MP: intermediate level P0 corresponds to final levels P0 (1111), P1 (1110), P7 (1101), and P8(1100); intermediate level P2 corresponds to final levels P2 (1010), P3 (1011), P6 (1001), and P9 (1000); intermediate level P4 corresponds to final levels P4 (0011), P5 (0001), P10 (0000), and P11 (0010); intermediate level P12 corresponds to final levels P12 (0110), P13 (0100), P14 (0101), and P15 (0111). It is understood that the designation of the intermediate levels and the mapping between intermediate levels and final levels may vary in different examples of 4-16 schemes based on the different Gray codes and data pages used for mapping.

Comparing the threshold voltages of each intermediate level and its corresponding final levels, the threshold voltage(s) of one or more final levels may be considered too larger than (too far away) that of the corresponding intermediate level, making the threshold voltage distributions of those final levels too wide (resulting in read window margins too small). For example, as shown in FIG. 11B, the threshold voltages of final levels P0 and P1 may be considered close to the threshold voltage of intermediate level P0, resulting in acceptable read window margins, whereas the threshold voltages of final levels P7 and P8 may be considered too far away from the threshold voltage of intermediate level P0, resulting in too small read window margins; the threshold voltages of final levels P2 and P3 may be considered close to the threshold voltage of intermediate level P2, resulting in acceptable read window margins, whereas the threshold voltages of final levels P6 and P9 may be considered too far away from the threshold voltage of intermediate level P2, resulting in too small read window margins; the threshold voltages of final levels P4 and P5 may be considered close to the threshold voltage of intermediate level P5, resulting in acceptable read window margins, whereas the threshold voltages of final levels P10 and P11 may be considered too far away from the threshold voltage of intermediate level P4, resulting in too small read window margins; the threshold voltages of final levels P12 and P13 may be considered close to the threshold voltage of intermediate level P12, resulting in acceptable read window margins, whereas the threshold voltage of final level P14 may be considered too far away from the threshold voltage of intermediate level P0, resulting in too small read window margins.

By introducing pre-programming between the coarse programming and fine programming, select memory cells 106 that are set to the final level that is too far away from the corresponding intermedia level can be first programmed to a pre-programmed level by the pre-programming between the final level and the intermediate level, thereby reducing the difference of threshold voltages that needs to be increased by the fine programming. As a result, the corresponding threshold voltage distribution of the final level can be tightened, and the read window margin can be enlarged. For example, as shown in FIG. 11B, memory cells set to final levels P7 and P8 may be programmed by the single voltage pulse Vpprm from intermediate level P0 to pre-programmed levels P7 and P8, respectively, by pre-programming, which may be considered close to final levels P7 and P8, respectively; memory cells set to final levels P6 and P9 may be programmed by the single voltage pulse Vpprm from intermediate level P2 to pre-programmed levels P6 and P9, respectively, by pre-programming, which may be considered close to final levels P6 and P9, respectively; memory cells set to final levels P10 and P11 may be programmed by the single voltage pulse Vpprm from intermediate level P4 to pre-programmed levels P10 and P11, respectively, by pre-programming, which may be considered close to final levels P10 and P11, respectively; memory cells set to final level P14 may be programmed by the single voltage pulse Vpprm from intermediate level P12 to pre-programmed level P14 by pre-programming, which may be considered close to final level P14.

As described above, the m pre-programmed levels (e.g., m=7, P6, P7, P8, P9, P10, P11, and P14 in FIG. 11B) may be determined based on the Gray code (e.g., in FIG. 11A) and the data pages used for mapping (e.g., LP and MP in FIG. 11A). Thus, it is understood that the designations of the m pre-programmed levels may vary in different examples of 4-16 schemes based on the different Gray codes and data pages used for mapping. It is also understood that even for the same Gray code and data pages used for mapping, the designations of the m pre-programmed levels may still vary in different examples based on the threshold voltage differences (distances) between the final levels and corresponding intermediate levels as described above. In any event, the number of pre-programmed levels is not greater than the difference between the number of final levels and the number of intermediate levels (m<2^{N}−k e.g., m<2^{N}−k in this example), according to some implementations.

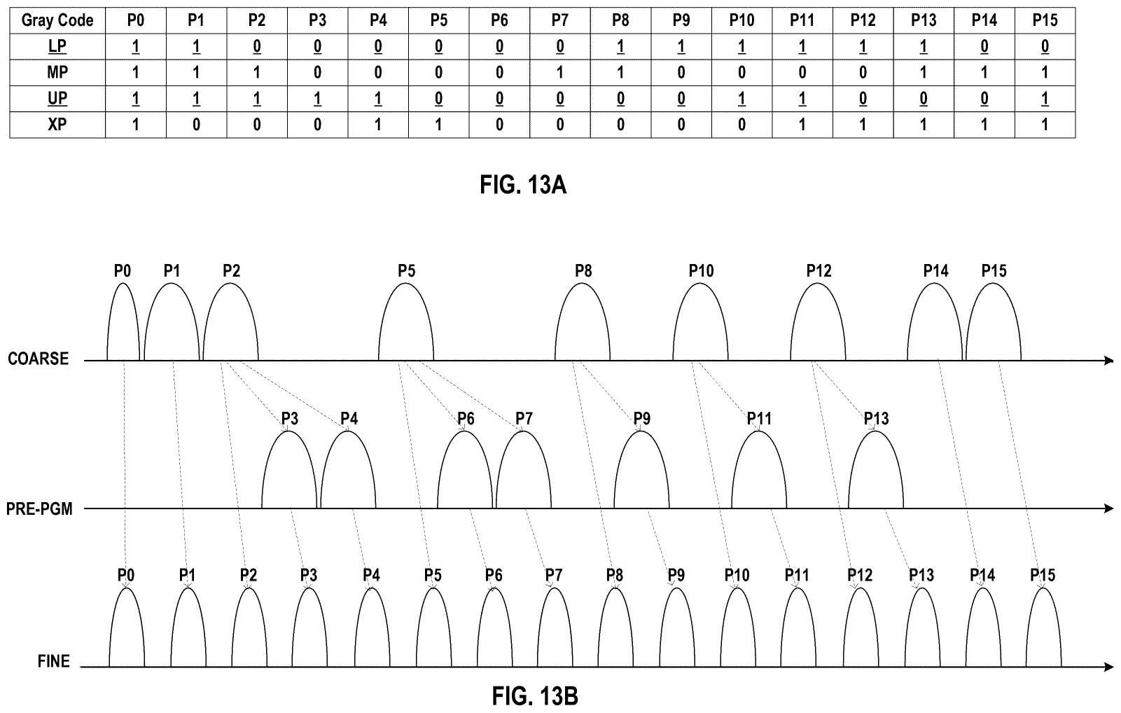

For example, FIG. 13A illustrates another example of a Gray code for the scheme of multi-pass program operation in FIG. 9, according to some aspects of the present disclosure. FIG. 13B illustrates another example of threshold voltage distributions of memory cells applying the scheme of multi-pass program operation in FIG. 9, according to some aspects of the present disclosure. In this scheme, N equals 4, k equals 9 (e.g., a 9-16 scheme for QLCs), and the m pre-programmed levels include P3, P4, P6, P7, P9, P11, and P13. As shown in FIG. 13A, four data pages (N=4 for QLCs) include a lower page LP, a middle page MP, an upper page UP, and an extra page XP, which are used for programming memory cells 106 into 9 intermediate levels by the coarse program pass and 16 final levels by the fine program pass according to the Gray code. In some implementations, “0” in the Gray codes indicates an inhibited status, and “1” in the Gray codes indicates a programming status. As shown in FIGS. 13A and 13B, 9 intermediate levels include P0 (11 for LP and UP), P1 (11 for LP and UP), P2 (01 for LP and UP), P5 (00 for LP and UP), P8 (10 for LP and UP), P10 (11 for LP and UP), P12 (10 for LP and UP), P14 (00 for LP and UP), and P15 (01 for LP and UP), according to some implementations. In some implementations, each intermediate level corresponds to one or more final levels that have the same values of lower page LP and upper page UP: intermediate level P0 corresponds to final level P0 (1111); intermediate level P1 corresponds to final level P1 (1110); intermediate level P2 corresponds to final levels P2 (0110), P3 (0010), and P4 (0011); intermediate level P5 corresponds to final levels P5 (0001), P6 (0000), and P7 (0100); intermediate level P8 corresponds to final levels P8 (1100) and P9 (1000); intermediate level P10 corresponds to final levels P10 (1010) and P11 (1011); intermediate level P12 corresponds to final levels P12 (1001) and P13 (1101); intermediate level P14 corresponds to final level P14 (0101); intermediate level P15 corresponds to final level P15 (0111). It is understood that the designation of the intermediate levels and the mapping between intermediate levels and final levels may vary in different examples of 9-16 schemes based on the different Gray codes and data pages used for mapping.

Comparing the threshold voltages of each intermediate level and its corresponding final levels, the threshold voltage(s) of one or more final levels may be considered too larger than (too far away) that of the corresponding intermediate level, making the threshold voltage distributions of those final levels too wide (resulting in read window margins too small). For example, as shown in FIG. 13B, the threshold voltage of final level P2 may be considered close to the threshold voltage of intermediate level P2, resulting in an acceptable read window margin, whereas the threshold voltages of final levels P3 and P4 may be considered too far away from the threshold voltage of intermediate level P2, resulting in too small read window margins; the threshold voltage of final level P5 may be considered close to the threshold voltage of intermediate level P5, resulting in an acceptable read window margin, whereas the threshold voltages of final levels P6 and P7 may be considered too far away from the threshold voltage of intermediate level P5, resulting in too small read window margins; the threshold voltages of final level P8 may be considered close to the threshold voltage of intermediate level P8, resulting in an acceptable read window margin, whereas the threshold voltage of final level P9 may be considered too far away from the threshold voltage of intermediate level P8, resulting in a too small read window margin; the threshold voltages of final level P10 may be considered close to the threshold voltage of intermediate level P10, resulting in an acceptable read window margin, whereas the threshold voltage of final level P11 may be considered too far away from the threshold voltage of intermediate level P10, resulting in a too small read window margin; the threshold voltages of final level P12 may be considered close to the threshold voltage of intermediate level P12, resulting in an acceptable read window margin, whereas the threshold voltage of final level P13 may be considered too far away from the threshold voltage of intermediate level P12, resulting in a too small read window margin.

By introducing pre-programming between the coarse programming and fine programming, select memory cells 106 that are set to the final level that is too far away from the corresponding intermedia level can be first programmed to a pre-programmed level by the pre-programming between the final level and the intermediate level, thereby reducing the difference of threshold voltages that needs to be increased by the fine programming. As a result, the corresponding threshold voltage distribution of the final level can be tightened, and the read window margin can be enlarged. For example, as shown in FIG. 13B, memory cells set to final levels P3 and P4 may be programmed by the single voltage pulse Vpprm from intermediate level P2 to pre-programmed levels P3 and P4, respectively, by pre-programming, which may be considered close to final levels P3 and P4, respectively; memory cells set to final levels P6 and P7 may be programmed by the single voltage pulse Vpprm from intermediate level P5 to pre-programmed levels P6 and P7, respectively, by pre-programming, which may be considered close to final levels P6 and P7, respectively; memory cells set to final level P9 may be programmed by the single voltage pulse Vpprm from intermediate level P8 to pre-programmed level P9 by pre-programming, which may be considered close to final level P9; memory cells set to final level P11 may be programmed by the single voltage pulse Vpprm from intermediate level P10 to pre-programmed level P11 by pre-programming, which may be considered close to final level P11; memory cells set to final level P13 may be programmed by the single voltage pulse Vpprm from intermediate level P12 to pre-programmed level P13 by pre-programming, which may be considered close to final level P13.

As described above, the m pre-programmed levels (e.g., m=7, P3, P4, P6, P7, P9, P11, and P13 in FIG. 13B) may be determined based on the Gray code (e.g., in FIG. 13A) and the data pages used for mapping (e.g., LP and UP in FIG. 13A). Thus, it is understood that the designations of the m pre-programmed levels may vary in different examples of 9-16 schemes based on the different Gray codes and data pages used for mapping. It is also understood that even for the same Gray code and data pages used for mapping, the designations of the m pre-programmed levels may still vary in different examples based on the threshold voltage differences (distances) between the final levels and corresponding intermediate levels as described above. In any event, the number of pre-programmed levels is not greater than the difference between the number of final levels and the number of intermediate levels (m<2^{N}−k, e.g., m=2^{N}−k in this example), according to some implementations

In some implementations, the amplitude of the single voltage pulse decreases over time. In some implementations, the amplitude of the single voltage pulse includes m discrete values each lasting for a respective period. In some implementations, a first memory cell of the at least some of the memory cells set to the highest level of the m pre-programmed levels is programmed in each of the m periods when applying the single voltage pulse. In some implementations, a second memory cell of the at least some of the memory cells set to the lowest level of the m pre-programmed levels is programmed in the last one of the m periods when applying the single voltage pulse. In some implementations, the second memory cell is inhibited in the rest of the m periods when applying the single voltage pulse.

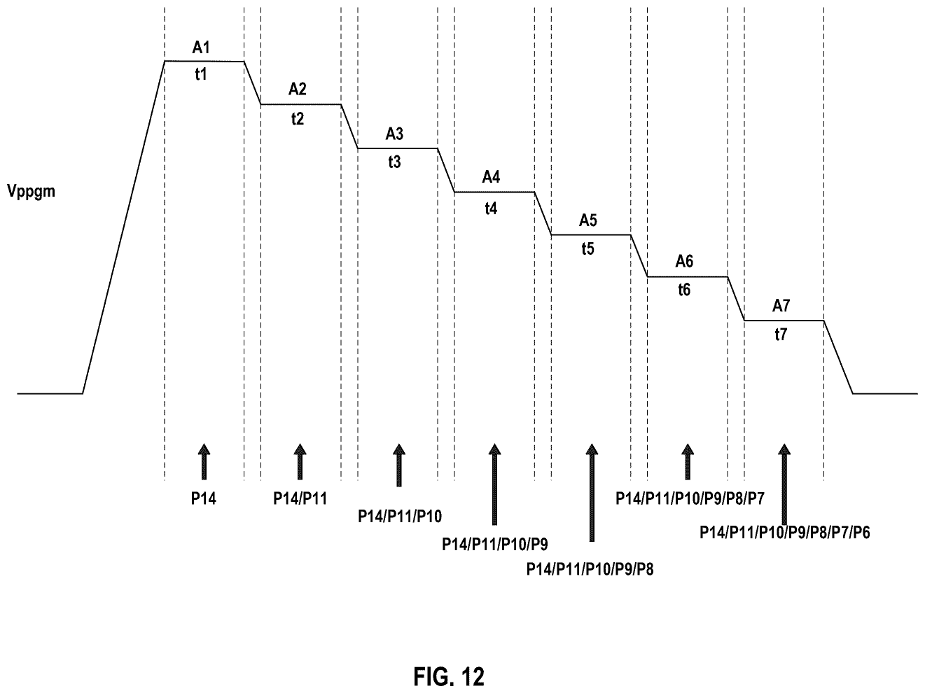

For example, FIG. 12 illustrates an example of a single voltage pulse used in the scheme of multi-pass program operation in FIG. 9, according to some aspects of the present disclosure. The single voltage pulse Vppgm in FIG. 12 may be used for pre-programming in the example of FIGS. 11A and 11B. The single voltage pulse Vppgm can decrease over time. In some implementations, as shown in FIG. 12, the amplitude of the single voltage pulse Vppgm includes 7 (m=7) discrete values A1, . . . A7, each lasting for a respective period t1, . . . , t7, and the values A1, . . . A7 of the amplitude decrease over time. In other words, the width of the single voltage pulse Vppgm can be divided into multiple periods with decreasing amplitude levels corresponding to the number of pre-programmed levels. The values A1, . . . A7 and/or the periods t1, . . . , t7 can be determined based on the threshold voltages of the corresponding pre-programmed levels, for example, to be sufficient while avoiding over-programming.

As shown in FIG. 12, in the first period t1, select memory cells 106 set to the highest pre-programmed level P14 are programmed at amplitude A1, while select memory cells 106 set to other pre-programmed levels P11, P10, P9, P8, P7, and P6 are inhibited; in the second period t2, select memory cells 106 set to the highest pre-programmed level P14 and the second highest pre-programmed level P11 are programmed at amplitude A2, while select memory cells 106 set to other pre-programmed levels P10, P9, P8, P7, and P6 are inhibited; in the third period t3, select memory cells 106 set to the highest pre-programmed level P14, the second highest pre-programmed level P11, and the third highest pre-programmed level P10 are programmed at amplitude A3, while select memory cells 106 set to other pre-programmed levels P9, P8, P7, and P6 are inhibited; in the fourth period t4, select memory cells 106 set to the highest pre-programmed level P14, the second highest pre-programmed level P11, the third highest pre-programmed level P10, and the fourth highest pre-programmed level P9 are programmed at amplitude A4, while select memory cells 106 set to other pre-programmed levels P8, P7, and P6 are inhibited; in the fifth period t5, select memory cells 106 set to the highest pre-programmed level P14, the second highest pre-programmed level P11, the third highest pre-programmed level P10, the fourth highest pre-programmed level P9, and the fifth highest pre-programmed level P8 are programmed at amplitude A5, while select memory cells 106 set to other pre-programmed levels P7 and P6 are inhibited; in the sixth period t6, select memory cells 106 set to the highest pre-programmed level P14, the second highest pre-programmed level P11, the third highest pre-programmed level P10, the fourth highest pre-programmed level P9, the fifth highest pre-programmed level P8, and the sixth highest pre-programmed level P7 are programmed at amplitude A6, while select memory cells 106 set to other pre-programmed level P6 are inhibited; in the last period t7, select memory cells 106 set to the highest pre-programmed level P14, the second highest pre-programmed level P11, the third highest pre-programmed level P10, the fourth highest pre-programmed level P9, the fifth highest pre-programmed level P8, the sixth highest pre-programmed level P7, and the lowest pre-programmed level P6 are programmed at amplitude A7.

That is, each select memory cell 106 set to the highest level (P14) of the 7 pre-programmed levels can be programmed in each of the 7 periods when applying the single voltage pulse Vppgm. As a result, the threshold distribution of final level P14 can be tightened, in particular, Vth-3σ. In contrast, each select memory cell 106 set to the lowest level (P6) of the 7 pre-programmed levels can be programmed in only the last one (t7) of the 7 periods when applying the single voltage pulse Vppgm. In any event, select memory cells 106 set to any pre-programmed levels other than the lowest level (P6) can be programmed in more than one time period when applying the single voltage pulse Vppgm to further tighten the threshold distributions of the corresponding final levels. On the other hand, select memory cell 106 can be inhibited in rest of the periods when applying the single voltage pulse Vppgm. That is, in each period, based on the Gray code, select memory cells 106 that are set to a pre-programmed level not currently being programmed in the period are inhibited to avoid being programmed since the pre-programming is performed in an SLC programming manner without verification, according to some implementations. As shown in FIG. 12, since the amplitude of the single voltage pulse Vppgm decreases over time, more and more select memory cells 106 can be released from inhibition over time and be pre-programmed, which cannot be achieved if the amplitude of the program voltage increases over time (e.g., the example of FIG. 9).

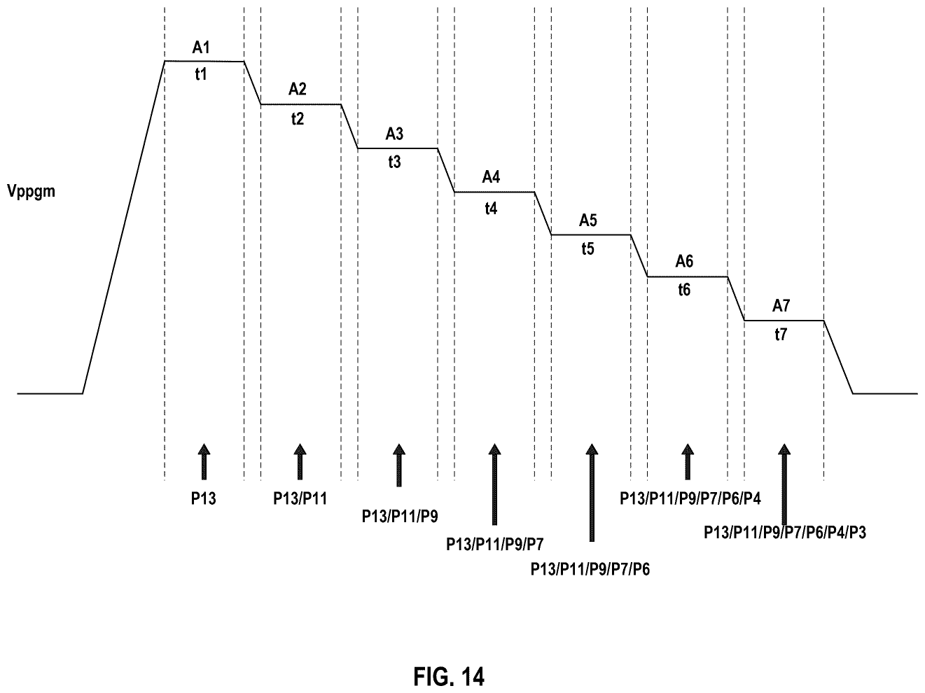

For example, FIG. 14 illustrates another example of a single voltage pulse used in the scheme of multi-pass program operation in FIG. 9, according to some aspects of the present disclosure. The single voltage pulse Vppgm in FIG. 14 may be used for pre-programming in the example of FIGS. 13A and 13B. The single voltage pulse Vppgm can decrease over time. In some implementations, as shown in FIG. 14, the amplitude of the single voltage pulse Vppgm includes 7 (m=7) discrete values A1, . . . A7, each lasting for a respective period t1, . . . , t7, and the values A1, . . . A7 of the amplitude decrease over time. In other words, the width of the single voltage pulse Vppgm can be divided into multiple periods with decreasing amplitude levels corresponding to the number of pre-programmed levels. The values A1, . . . A7 and/or the periods t1, . . . , t7 can be determined based on the threshold voltages of the corresponding pre-programmed levels, for example, to be sufficient while avoiding over-programming.

As shown in FIG. 14, in the first period t1, select memory cells 106 set to the highest pre-programmed level P13 are programmed at amplitude A1, while select memory cells 106 set to other pre-programmed levels P11, P9, P7, P6, P4, and P3 are inhibited; in the second period t2, select memory cells 106 set to the highest pre-programmed level P13 and the second highest pre-programmed level P11 are programmed at amplitude A2, while select memory cells 106 set to other pre-programmed levels P9, P7, P6, P4, and P3 are inhibited; in the third period t3, select memory cells 106 set to the highest pre-programmed level P13, the second highest pre-programmed level P11, and the third highest pre-programmed level P9 are programmed at amplitude A3, while select memory cells 106 set to other pre-programmed levels P7, P6, P4, and P3 are inhibited; in the fourth period t4, select memory cells 106 set to the highest pre-programmed level P13, the second highest pre-programmed level P11, the third highest pre-programmed level P9, and the fourth highest pre-programmed level P7 are programmed at amplitude A4, while select memory cells 106 set to other pre-programmed levels P6, P4, and P3 are inhibited; in the fifth period t5, select memory cells 106 set to the highest pre-programmed level P13, the second highest pre-programmed level P11, the third highest pre-programmed level P9, the fourth highest pre-programmed level P7, and the fifth highest pre-programmed level P6 are programmed at amplitude A5, while select memory cells 106 set to other pre-programmed levels P4 and P3 are inhibited; in the sixth period t6, select memory cells 106 set to the highest pre-programmed level P13, the second highest pre-programmed level P11, the third highest pre-programmed level P9, the fourth highest pre-programmed level P7, the fifth highest pre-programmed level P6, and the sixth highest pre-programmed level P4 are programmed at amplitude A6, while select memory cells 106 set to other pre-programmed level P3 are inhibited; in the last period t7, select memory cells 106 set to the highest pre-programmed level P13, the second highest pre-programmed level P11, the third highest pre-programmed level P9, the fourth highest pre-programmed level P7, the fifth highest pre-programmed level P6, the sixth highest pre-programmed level P4, and the lowest pre-programmed level P3 are programmed at amplitude A7.

That is, each select memory cell 106 set to the highest level (P13) of the 7 pre-programmed levels can be programmed in each of the 7 periods when applying the single voltage pulse Vppgm. As a result, the threshold distribution of final level P13 can be tightened, in particular, Vth-3σ. In contrast, each select memory cell 106 set to the lowest level (P3) of the 7 pre-programmed levels can be programmed in only the last one (t7) of the 7 periods when applying the single voltage pulse Vppgm. In any event, select memory cells 106 set to any pre-programmed levels other than the lowest level (P3) can be programmed in more than one time period when applying the single voltage pulse Vppgm to further tighten the threshold distributions of the corresponding final levels. On the other hand, select memory cell 106 can be inhibited in the rest of the periods when applying the single voltage pulse Vppgm. That is, in each period, based on the Gray code, select memory cells 106 that are set to a pre-programmed level not currently being programmed in the period are inhibited to avoid being programmed since the pre-programming is performed in an SLC programming manner without verification, according to some implementations. As shown in FIG. 14, since the amplitude of the single voltage pulse Vppgm decreases over time, more and more select memory cells 106 can be released from inhibition over time and be pre-programmed, which cannot be achieved if the amplitude of the program voltage increases over time (e.g., the example of FIG. 9).

Method 1500 proceeds to operation 1506, as illustrated in FIG. 15, in which, after applying the single voltage pulse, in a second pass, the select row of the memory cells are programmed, such that the memory cells in the selected row are set to the 2^{N} final levels. In some implementations, programming the select row of the memory cells, such that the memory cells in the selected row are set to the 2^{N} final levels, occurs immediately after applying the single voltage pulse without applying a verify voltage to the select word line therebetween.

For example, in the multi-pass program operation, peripheral circuit 102 can be configured to program, in second pass 602b (e.g., a fine program pass) after pre-programming, select row of memory cells 106 based on the N data pages, such that each memory cell 106 of the selected row is set to one of the 2^{N} final levels. As shown in FIG. 10, second pass 602b may occur immediately after applying the single voltage pulse Vpprm without applying a verify voltage Vvfy. The 2^{N} final levels can correspond to 2^{N} threshold voltage ranges, respectively, of the select row of memory cells 106. In some implementations, to program the select row of memory cells 106 in second pass 602b, word line driver 308 is configured to apply, in program cycle 702, 704, . . . , or 706, a first program voltage Vpgm (e.g., a fine program voltage) to select word line 118, and then apply, in verify cycle 708, 710, . . . , or 712, a set of first verify voltages Vvfy (e.g., fine verify voltages) to select word line 118 for verifying and thus, forming the final levels. For example, the set of fine verify voltages may include (2^{N}−1) verify voltages for verifying and forming 2^{N} final levels in second pass 602b. As shown in FIGS. 11B and 13B, a final level may be programmed directly from a corresponding intermediate level (e.g., final levels P0, P1, P2, P3, P4, P5, P12, P13, and P15 in FIG. 11B, and final levels P0, P1 P2, P5, P8, P10, P12, P14, and P15 in FIG. 13B) or from a corresponding pre-programmed level (e.g., final levels P6, P7, P8, P9, P10, P11, and P14 in FIG. 11B, and P6, P7, P8, P9, P10, P11, and P14 in FIG. 13B) as described above in detail.

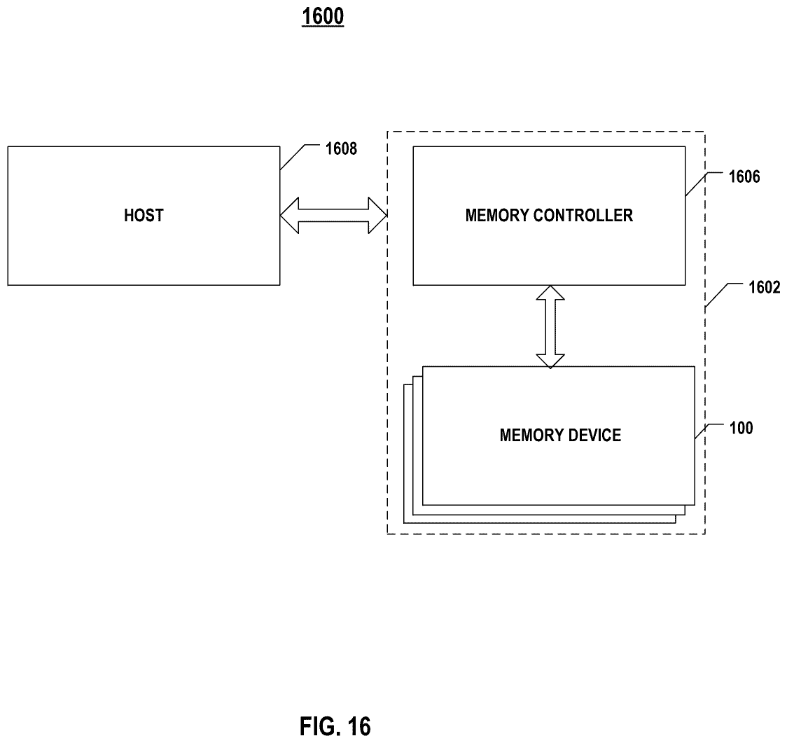

FIG. 16 illustrates a block diagram of a system 1600 having a memory device, according to some aspects of the present disclosure. System 1600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 16, system 1600 can include a host 1608 and a memory system 1602 having one or more memory devices 100 (shown in FIG. 1) and a memory controller 1606. Host 1608 can be a processor of an electronic device, such as a central processing unit (CPU), or a system-on-chip (SoC), such as an application processor (AP). Host 1608 can be configured to send or receive data to or from memory devices 100.

Memory device 100 can be any memory device disclosed in the present disclosure. Memory controller 1606 is coupled to memory device 100 and host 1608 and is configured to control memory device 100, according to some implementations. Memory controller 1606 can manage the data stored in memory device 100 and communicate with host 1608. In some implementations, memory controller 1606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1606 can be configured to control operations of memory device 100, such as read, erase, and program operations. Memory controller 1606 can also be configured to manage various functions with respect to the data stored or to be stored in memory device 100 including, but not limited to bad-block management, garbage collection, logical-to-physical address conversion, wear leveling, etc. In some implementations, memory controller 1606 is further configured to process error correction codes (ECCs) with respect to the data read from or written to memory device 100. Any other suitable functions may be performed by memory controller 1606 as well, for example, formatting memory device 100. Memory controller 1606 can communicate with an external device (e.g., host 1608) according to a particular communication protocol. For example, memory controller 1606 may communicate with the external device through at least one of various interface protocols, such as a USB protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Consistent with the scope of the present disclosure, memory controller 1606 can transmit program commands to memory device 100 to control memory device 100 to perform the program operations described herein. In some implementations, memory controller 1606 transmits a first program command to memory device 100 to control memory device 100 to perform the coarse programming in first pass 602a, and then transmit a second program command to memory device 100 to control memory device 100 to perform the fine programming in second pass 602b and pre-programming 1001 ahead of the fine programming.

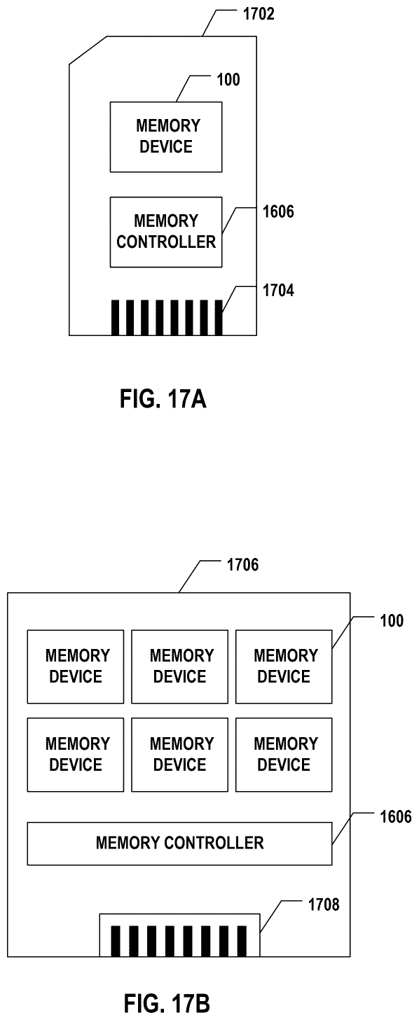

Memory controller 1606 and one or more memory devices 100 can be integrated into various types of storage devices, for example, being included in the same package, such as a universal Flash storage (UFS) package or an eMMC package. That is, memory system 1602 can be implemented and packaged into different types of end electronic products. In one example as shown in FIG. 17A, memory controller 1606 and a single memory device 100 may be integrated into a memory card 1702. Memory card 1702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1702 can further include a memory card connector 1704 coupling memory card 1702 with a host (e.g., host 1608 in FIG. 16). In another example as shown in FIG. 17B, memory controller 1606 and multiple memory devices 100 may be integrated into an SSD 1706. SSD 1706 can further include an SSD connector 1708 coupling SSD 1706 with a host (e.g., host 1608 in FIG. 16). In some implementations, the storage capacity and/or the operation speed of SSD 1706 is greater than those of memory card 1702.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

Although specific configurations and arrangements are discussed, it should be understood that this is done for illustrative purposes only. As such, other configurations and arrangements can be used without departing from the scope of the present disclosure. Also, the subject matter as described in the present disclosure can also be used in a variety of other applications. Functional and structural features as described in the present disclosures can be combined, adjusted, modified, and rearranged with one another and in ways that are consistent with the scope of the present disclosure.

What is claimed is:

1. A memory device, comprising:
an array of memory cells, each memory cell being set to one of 2^{N} final levels corresponding to a piece of N-bits data, where N is an integer greater than 2;
word lines respectively coupled to rows of the memory cells; and
a peripheral circuit coupled to the array of memory cells through the word lines and configured to:
program, in a first pass, a select row of the rows of the memory cells, such that the memory cells in the selected row are set to k intermediate levels, where k is an integer not greater than 2^{N};
after the first pass, apply a single voltage pulse to a select word line of the word lines coupled to the select row of the memory cells, wherein an amplitude of the single voltage pulse changes over time; and
after applying the single voltage pulse, program, in a second pass, the select row of the memory cells, such that the memory cells in the selected row are set to the 2^{N} final levels.

2. The memory device of claim 1, wherein the amplitude of the single voltage pulse decreases over time.

3. The memory device of claim 1, wherein at least some of the memory cells in the select row are set to m pre-programmed levels by applying the single voltage pulse, where m is an integer not greater than 2^{N}−k.

4. The memory device of claim 3, wherein the m pre-programmed levels are determined based on a Gray code for programming the select row of the memory cells.

5. The memory device of claim 4, wherein N equals 4, k equals 4, and the m pre-programmed levels comprise P6, P7, P8, P9, P10, P11, and P14.

6. The memory device of claim 4, wherein N equals 4, k equals 9, and the m pre-programmed levels comprise P3, P4, P6, P7, P9, P11, and P13.

7. The memory device of claim 3, wherein the amplitude of the single voltage pulse comprises m discrete values each lasting for a respective period.

8. The memory device of claim 7, wherein a first memory cell of the at least some of the memory cells set to a highest level of the m pre-programmed levels is programmed in each of the m periods when applying the single voltage pulse.

9. The memory device of claim 7, wherein a second memory cell of the at least some of the memory cells set to a lowest level of the m pre-programmed levels is programmed in a last one of the m periods when applying the single voltage pulse.

10. The memory device of claim 9, wherein the second memory cell is inhibited in rest of the m periods when applying the single voltage pulse.

11. The memory device of claim 1, wherein the peripheral circuit is configured to program the select row of the memory cells, such that the memory cells in the selected row are set to the 2^{N} final levels, immediately after applying the single voltage pulse without applying a verify voltage to the select word line there between.

12. A method for operating a memory device comprising rows of memory cells, each memory cell being set to one of 2^{N} final levels corresponding to a piece of N-bits data, where N is an integer greater than 2, the method comprising:
programming, in a first pass, a select row of the rows of the memory cells, such that the memory cells in the selected row are set to k intermediate levels, where k is an integer not greater than 2^{N};
after the first pass, applying a single voltage pulse to a select word line coupled to the select row of the memory cells, wherein an amplitude of the single voltage pulse changes over time; and
after applying the single voltage pulse, programming, in a second pass, the select row of the memory cells, such that the memory cells in the selected row are set to the 2^{N} final levels.

13. The method of claim 12, wherein the amplitude of the single voltage pulse decreases over time.

14. The method of claim 12, wherein at least some of the memory cells in the select row are set to m pre-programmed levels by applying the single voltage pulse, where m is an integer not greater than 2^{N}−k.

15. The method of claim 14, wherein the m pre-programmed levels are determined based on a Gray code for programming the select row of the memory cells.

16. The method of claim 14, wherein the amplitude of the single voltage pulse comprises m discrete values each lasting for a respective period.

17. The method of claim 16, wherein a first memory cell of the at least some of the memory cells set to a highest level of the m pre-programmed levels is programmed in each of the m periods when applying the single voltage pulse.

18. The method of claim 16, wherein a second memory cell of the at least some of the memory cells set to a lowest level of the m pre-programmed levels is programmed in a last one of the m periods when applying the single voltage pulse.

19. The method of claim 12, wherein programming the select row of the memory cells, such that the memory cells in the selected row are set to the 2^{N} final levels, occurs immediately after applying the single voltage pulse without applying a verify voltage to the select word line therebetween.

20. A system, comprising:
a memory device configured to store data, the memory device comprising:
an array of memory cells, each memory cell being set to one of 2^{N} final levels corresponding to a piece of N-bits data, where N is an integer greater than 2;
word lines respectively coupled to rows of the memory cells; and
a peripheral circuit coupled to the array of memory cells through the word lines and configured to:
program, in a first pass, a select row of the rows of the memory cells, such that the memory cells in the selected row are set to k intermediate levels, where k is an integer not greater than 2^{N};
after the first pass, apply a single voltage pulse to a select word line of the word lines coupled to the select row of the memory cells, wherein an amplitude of the single voltage pulse changes over time; and
after applying the single voltage pulse, program, in a second pass, the select row of the memory cells, such that the memory cells in the selected row are set to the 2^{N} final levels; and
a memory controller coupled to the memory device and configured to control the memory device.
